(19) United States
(12) Patent Application Publication
(10) Pub. No.: US 2004/0012077 A1
(43) Pub. Date: Jan. 22, 2004

(54) Semiconductor leadframes having dual surface finish for varied molding compound adhesion

(76) Inventors: Mohd A. Ibrahim, Kuala Lumpur (MY); James R. Huckabee, Sherman, TX (US)

Correspondence Address: TEXAS INSTRUMENTS INCORPORATED, P O BOX 655474, M/S 3999, DALLAS, TX, 75265

(21) Appl. No.: 10/200,277

(22) Filed: Jul. 22, 2002

(51) Int. Cl. H01L 23/495; H01L 21/50

(52) U.S. Cl. 257/666; 438/123

(57) ABSTRACT

A leadframe strip for use in the assembly of integrated circuit devices, which is made from a sheet of base metal and comprises a series of leadframe units formed in this base metal. The units are arranged in linear progression so that each unit is interconnected with its adjacent neighbors by supporting rails. The rails are positioned along the outer edges of the strip, thus holding the strip together. The strip has a surface configuration for the leadframe units such that the surface maximizes adhesion to the encapsulation material. The strip further has a surface configuration for the rails such that the surface minimizes adhesion to the encapsulation material.

### BACKGROUND OF THE INVENTION

The present invention is related in general to the field of semiconductor devices and processes and more specifically to the materials and fabrication of leadframes for integrated circuit devices.

### DESCRIPTION OF THE RELATED ART

The leadframe for semiconductor devices was invented (U.S. Pat. Nos. 3,716,764 and 4,034,027) to serve several needs of semiconductor devices and their operation simultaneously: First of all, the leadframe provides a stable support pad for firmly positioning the semiconductor chip, usually an integrated circuit (IC) chip. Since the leadframe including the pads is made of electrically conductive material, the pad may be biased, when needed, to any electrical potential required by the network involving the semiconductor device, especially the ground potential.

Secondly, the leadframe offers a plurality of conductive segments to bring various electrical conductors into close proximity of the chip. The remaining gap between the (“inner”) tip of the segments and the conductor pads on the IC surface are typically bridged by thin metallic wires individually bonded to the IC contact pads and the leadframe segments. Obviously, the technique of wire bonding implies that reliable welds can be formed at the (inner) segment tips.

Thirdly, the ends of the lead segment remote from the IC chip (“outer” tips) need to be electrically and mechanically connected to “other parts” or the “outside world”, for instance to assembly printed circuit boards. In the overwhelming majority of electronic applications, this attachment is performed by soldering. Obviously, the technique of soldering implies that reliable wetting and solder contact can be performed at the (outer) segment tips.

It has been common practice to manufacture single piece leadframes from thin (about 120 to 250 μm) sheets of metal. For reasons of easy manufacturing, the commonly selected starting metals are copper, copper alloys, iron-nickel alloys (for instance the so-called “Alloy 42”), and invar. The desired shape of the leadframe is etched or stamped from the original sheet. In this manner, an individual unit of the leadframe takes the form of a thin metallic strip with its particular geometric shape determined by the design. For most purposes, the length of a typical unit is considerably longer than its width.

A plurality of units is typically arranged in linear progression, forming a leadframe “strip”. Along the strip, the units are held together by “rails”, which provide the mechanical support needed to guide each strip through the various steps of the fabrication process.

In the European patent #0 335 608 B1, issued Jun. 14. 1995 (Abbott, “Leadframe with Reduced Corrosion”), U.S. Pat. No. 6,194,777, issued Feb. 27, 2001 (Abbott, “Leadframes with Selective Palladium Plating”), and U.S. Pat. No. 6,246,446, issued Jun. 12, 2001 (Abbott, “Leadframe with Reduced Corrosion”), a palladium-plated leadframe is introduced which is not subject to corrosion due to galvanic potential forces aiding the migration of the base metal ions to the top surface where they will form corrosion products. The patent describes a sequence of layers consisting of nickel (over the base metal), palladium/nickel alloy, nickel, and palladium (outermost). This technology has been widely accepted by the semiconductor industry.

After assembly on the leadframe, most ICs are encapsulated, commonly by plastic material in a molding process. The preferred method is the transfer molding technique, wherein the molding compound is pressured through narrow “gates” into the cavity, in which the leadframe strip with the assembled chips has been positioned. It is essential that the molding compound, usually an epoxy-based thermoset compound, has good adhesion to the leadframe and the device parts it encapsulates. Palladium, described above as the outermost layer of the leadframe, offers excellent adhesion to molding compounds.

On the other hand, it is vital for a trouble-free, low cycle time manufacturing flow that each leadframe strip can be removed from the mold without undue adhesion of the leadframe rails to the molding compound remaining in the compound supply lines, the so-called “gate runners”. A leadframe strip with uniformly good adhesion to molding compound impedes the easy separation from the compound in the gate runners and thus makes the manufacturing flow difficult.

An urgent need has therefore arisen for a low-cost, reliable mass production method for a leadframe combining the advantages of palladium with its bondability and adhesion capability to molding compounds, and the easy separation of the leadframe strip from the molding compound remaining the gate runner supply lines. The leadframe and its method of fabrication should be flexible enough to be applied for different semiconductor product families and a wide spectrum of design and assembly variations, and should achieve improvements toward the goals of improved process yields and device reliability. Preferably, these innovations should be accomplished using the installed equipment base so that no investment in new manufacturing machines is needed.

### SUMMARY OF THE INVENTION

A leadframe strip for use in the assembly of integrated circuit devices is described, which is made from a sheet of base metal and comprises a series of leadframe units formed in this base metal. The units are arranged in linear progression so that each unit is interconnected with its adjacent neighbors by supporting rails. The rails are positioned along the outer edges of the strip, thus holding the strip together. The strip has a surface configuration for the leadframe units such that the surface maximizes adhesion to the encapsulation material. The strip further has a surface configuration for the rails such that the surface minimizes adhesion to the encapsulation material.

In a preferred embodiment, an adherent first metal layer on the base metal comprises nickel, and an adherent second layer on the nickel layer comprises a metal, such as palladium, selected for improved adherence to encapsulation compounds and bonding wires. The second layer is selectively placed on the units, leaving the rails uncovered.

The present invention is related to high volume semiconductor products, for which manufacturing cycle time and yield are greatly influenced by the efficiency of the encapsulation (especially molding) process steps.

The present invention is also related to high density ICs, especially those having high numbers of inputs/outputs, or contact pads, and also to devices in packages requiring surface mount in printed circuit board assembly. These ICs can be found in many semiconductor device families such as standard linear and logic products, digital signal processors, microprocessors, digital and analog devices, and both large and small area chip categories. The invention represents a significant manufacturing cycle time and cost reduction, and enhances environmental protection and assembly flexibility of semiconductor packages, especially the plastic molded packages, compared to the conventional copper-based leadframes.

It is an aspect of the present invention to have different leadframe surface finishes for the supporting rails relative to the device proper, wherein both are determined by the encapsulation compound of the device.

In a preferred embodiment, leadframe rails have smooth nickel surface and leadframe units have rough nickel surface.

In another preferred embodiment, leadframe rails have nickel surface and leadframe units palladium surface.

Another aspect of the invention is to reach these goals with a low-cost manufacturing method without the cost of equipment changes and new capital investment, by using the installed fabrication equipment base.

The invention may utilize a wheel-based plating system to deposit the nickel and palladium layers.

Another aspect of the invention is to produce leadframes so that established wire bonding processes can continue unchanged, and that established board attachment process can continue unchanged.

Another aspect of the invention is to utilize manufacturing transfer molding equipment and processes without changes.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic and simplified cross section of portions of a molding system showing the plunger, a gate runner, and portions of a leadframe strip loaded in mold cavities.

FIG. 2A is a schematic top view of portions of a molding system showing the plunger, portions of a leadframe strip with a plurality of molded devices, and the residual molding compounds in the gate runners attached to the leadframe rail.

FIG. 2B is a magnified portion of FIG. 2A.

FIG. 3A shows a schematic cross section of a portion of a molding system, when a leadframe rail is still attached to the residual molding compound in the gate runner.

FIG. 3B shows a schematic cross section of a portion of a molding system at the moment when a leadframe rail is separated from the residual molding compound in the gate runner.

### DETAILED DESCRIPTION OF THE PREFERRED EMBODIMENTS

The present invention is related to U.S. Applications No. 10/073,523, filed on Feb. 11, 2002 (Abbott, “Method for Fabricating Preplated Nickel/Palladium and Tin Leadframes”), and No. 10/061,823, filed on Feb. 1, 2002 (Abbott et al., “Semiconductor Leadframes Plated with Tick Nickel, Minimum Palladium, and Pure Tin”), which are herewith incorporated by reference.

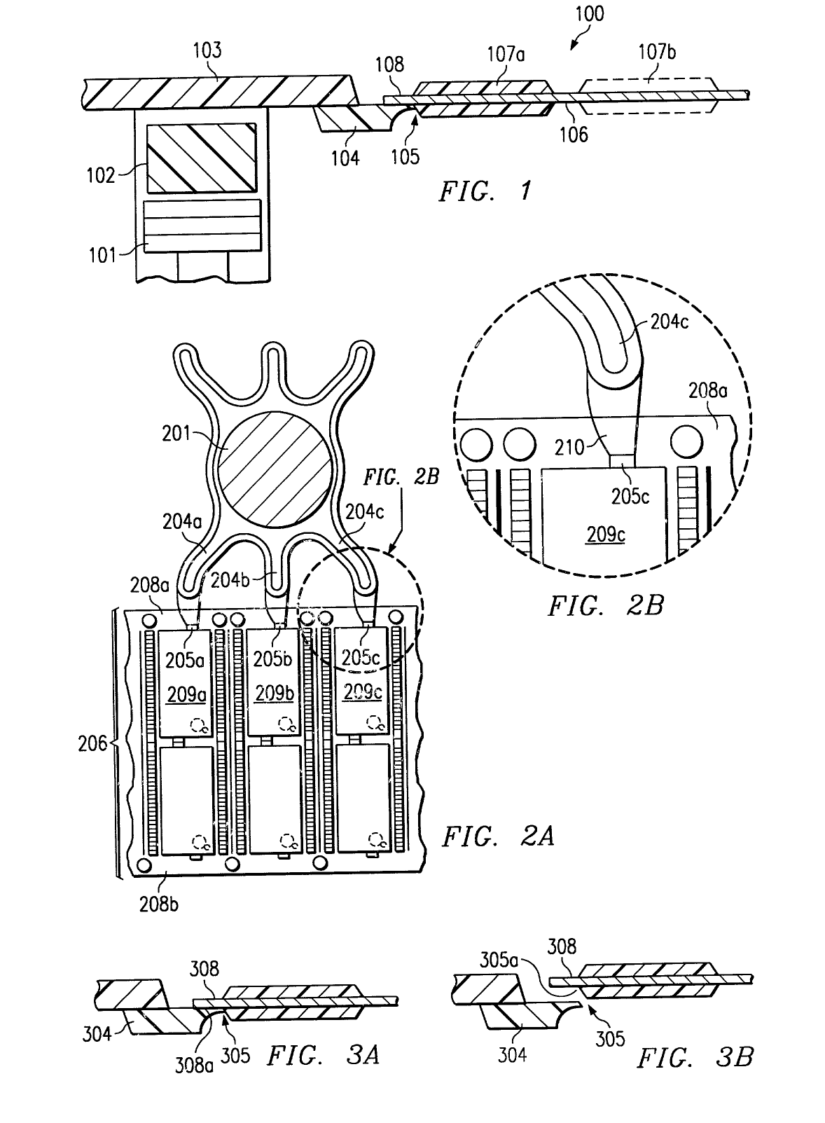

The cross section of FIG. 1 illustrates schematically a small portion, generally designated 100, of a molding system in which a plunger 101 is used to pressure semi-viscous molding compound 102 into cull 103 and runners 104 leading to the cavities loaded with the semiconductor devices to be encapsulated. In FIG. 1, the runners 104 are the so-called gate runners. They connect to the gates 105 of the cavities to be filled with molding compound. The runners and gates are crucial features in the design of a mold, because the flow rate of the semi-viscous molding material is determined by the force of the moving plunger 101, the lengths and cross sections of the runners 103 and 104, the cross section of the gates 105, the temperature of the transfer operation, and the viscous and flow characteristics of the molding material.

FIG. 1 further shows the leadframe strip 106 with the plurality of assembled IC chips. Each chip is positioned in its own mold cavity 107a, 107b, etc. The rail 108 of the leadframe strip 106 is resting on, and supported by, the mold steel which surrounds the gate runner 104. Consequently, the leadframe metal of the rail will be in contact with the molding compound, before the compound enters through gate 105 into the cavity 107a. After completion of the molding process, the bit of molding compound in the gate runner 104 will remain in contact with the rail metal 108 throughout the cool-down from the molding temperature.

It is obviously a drawback for quick removal of the finished product from the mold (cycle time) if the adhesion between the rail 108 and the compound in runner 104 is strong and thus prevents an easy separation.

FIG. 2A illustrates the leadframe strip 206 and its rails 208a and 208b in relation to the plunger 201 and gate runners 204a, 204b, and 204c in a schematic top view. Each runner has supplied molding material to the gates 205a, 205b, and 205c, respectively, in order to encapsulate the devices 209a, 209b, and 209c, respectively. After the transfer molding process has been completed, the load is cooled down from the molding temperature (typically between 165 and 185° C.).

FIG. 2B is a magnified view of a portion of FIG. 2A. As can be clearly seen, a portion 210 of the cooled molding compound remains in contact with the surface of 208a. With the teaching of the present invention, an adhesion of compound 210 on the surface of rail 208a can be prevented, so that the leadframe strip 206 can be easily removed from the mold. No mechanical breaking, with its risk of damage to the gate or of cracks in the plastic device encapsulation, or any later chemical clean-up is required.

FIGS. 3A and 3B depict the separation step in detail. In FIG. 3A, surface 308a of leadframe rail 308 is in contact the hardened molding compound in gate runner 304. According to the teachings of the present invention, however, there is minimal or no adhesion between surface 308a and the molding compound. Consequently, the separation between rail 308 and the compound in runner 304 can be accomplished without any problem. The breakage of the compound at gate 305 is easy and clean. The encapsulation of the molded device shows only a barely visible breakage mark.

As defined herein, the starting material of the leadframe is called the “base metal”, indicating the type of metal. Consequently, the term “base metal” is not to be construed in an electrochemical sense (as in opposition to ‘noble metal’) or in a structural sense. The base metal of leadframes is typically copper or copper alloys. Other choices comprise brass, aluminum, iron-nickel alloys (“Alloy 42”), and invar.

Leadframe surfaces have to comprise adhesion to molding compounds. This can be achieved in a number of ways.

Molding compound manufacturers are producing compounds which adhere to the leadframe metal, commonly copper. (It may, however, be difficult for these compounds to simultaneously satisfy numerous other attributes, which a molding compound for semiconductor devices has to fulfill, such as moldability, stability, strength, thermal characteristics).

Minimized adhesion of the leadframe rails can be provided in several ways:

Selectively cover the rails with a non-adhesive tape;

selectively oxidize the rail surfaces;

other selective means in conjunction with the molding compound chosen.

A layer of nickel is plated, fully covering the leadframe base metal. Sometimes, a layer of pure tin is preplated onto the nickel layer only onto those leadframe areas which are intended for external parts attachment (such as printed circuit boards, substrates, etc.). Furthermore, adhesion to molding compounds may be enhanced by plating a thin layer of palladium on the nickel layer. This layer may only selectively cover areas of the leadframe which are intended for bonding wire attachment, chip attachment, and other areas. For palladium, a thin layer is sufficient for reliable bonding wire attachment (stitch bonds, ball bonds, or wedge bonds).

Minimized adhesion of the leadframe rails can be provided by:

No palladium plating on rail areas;

No palladium plating on rail areas and selective exposure of the nickel in rail areas to oxidation.

A first layer of nickel is plated, fully covering the leadframe base metal; this nickel layer is smooth as usual. Subsequently, the leadframe strip is run through another plating bath having a buffer salt added the nickel bath, creating a nickel layer with rough surface. This second nickel layer is plated selectively on leadframe areas where good adhesion is desired, but not on the rail areas. Optionally, a thin palladium layer is deposited.

Minimized adhesion of the leadframe rails can be provided by:

Leaving the nickel layer with the smooth surface; avoiding the deposition of nickel with the rough surface;

avoiding the deposition of the additional palladium layer on the rail areas.

Preferred base metal and layer thicknesses are: The base metal usually is copper or copper alloy, but may also be aluminum, brass, an iron-nickel alloy, or invar in the preferred thickness range from 100 to 300 μm; thinner sheets are possible. The leadframe is stamped or etched from the starting metal sheet. The plated nickel layer has a preferred thickness is the range from about 0.2 to 3.0 μm. The palladium layer has a preferred thickness range from 20 to 75 nm. If gold is used in conjunction with the palladium, its thickness is in the range from 2 to 5 nm.

In the plating process, the stamped or etched leadframe is first immersed in an alkaline preclean solution at 20 to 90° C. for few seconds up to 3 minutes. Both alkaline soak cleaning and alkaline electrocleaning are employed. Oils, grease, soil, dirt and other contamination are thereby removed.

After rinsing, the leadframe is next immersed in an acid activation bath at room temperature for few seconds up to 5 minutes. The bath consists of a solution of sulfuric acid, hydrochloric acid, or other acid solution, preferably at about 30 to 60 g/l concentration. This solution removes copper oxide and leaves the metallic copper surface in an activated state, ready to accept the deposition of metallic nickel.

Next, the leadframe is immersed in a first nickel plating solution to receive the deposition onto the copper base material of a nickel strike in the thickness range of about 0.02 to 0.13 μm. This first nickel layer fully encases the copper base metal and thus keeps the subsequent main nickel bath free from copper and copper compounds.

Next, the leadframe is immersed in a second nickel plating solution to receive the deposition onto the first nickel layer of an additional nickel layer in the thickness range of about 0.45 to 2.0 μm. The total thickness range of layer 104 is approximately 0.5 to 3.0 μm. This nickel layer has to be ductile for the leadframe segment bending and forming process. Further, the nickel surface has to be wettable in the soldering process, so that solder alloys or conductive adhesives can be used successfully.

It is an important aspect of the present invention to deposit the palladium layer selectively onto the leadframe by using an inexpensive masking step. The selective characteristic of the palladium deposition is achieved by a temporary masking step, which leaves only those leadframe portions exposed which are intended to receive the palladium layer.

There are several methods to selectively deposit metals from solution onto a continuous strip. For high volume production of leadframes, continuous strip or reel-to-reel plating is advantageous and common practice. Based on the loose tolerance acceptable for the boundaries of the palladium plating on the inner ends of the lead segments, the preferred deposition method for the present invention is the so-called “wheel system”. The process steps are as follows.

WHEEL SYSTEM

Material is moved over a large diameter wheel with apertures in it to allow solution flow to material;

apertures define the locations for plating; index pins engage the pilot holes in the leadframe;

backing belt is used to hold material on wheel and mask backside of material;

anode is stationary inside wheel.

Advantages: Fast, material never stops for selective plating; no timing issues; pumps, rectifiers, and drive system are on continuously; low cost because system is mechanically uncomplicated.

Disadvantages: Loose plating boundaries, poor spot location, and potential bleedout are not critical issues for the present invention.

A more precise, but also more costly and slower selective plating technique is the step-and-repeat process.

STEP AND REPEAT

Leadframe material is stopped in selective plating head;

rubber mask system clamps on material;

plating solution is jetted at material;

current is applied;

current is shut off;

solution is shut off;

head opens;

material moves.

Advantages: Very sharp plating spot with excellent edge definition; very good spot location capability when used with index holes, pins and feedback vision system.

Disadvantages: Slow; material must stop during selective plating; expensive equipment to buy and maintain; timing issues; lots of moving parts.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the designs, cover areas and fabrication methods of the tin layer and of the palladium layer may be modified to suit specific leadframe or substrate needs. It is therefore intended that the appended claims encompass any such modifications or embodiments.

We claim:

1. A leadframe strip for use in the assembly and packaging of integrated circuit devices, said strip made from a sheet of base metal and said packaging including encapsulation material, comprising:
a series of leadframe units formed in said base metal and arranged in linear progression so that each unit is interconnected with its adjacent neighbors by supporting rails, wherein said rails are positioned along the outer edges of said strip, thus holding said strip together;
a surface configuration of said base metal for said leadframe units such that said surface maximizes adhesion to said encapsulation material; and
a surface configuration of said base metal for said rails such that said surface minimizes adhesion to said encapsulation material.

2. The leadframe strip according to claim 1 wherein said base metal is copper, copper alloy, aluminum, iron-nickel alloy, or invar.

3. The leadframe strip according to claim 1 wherein said sheet metal has a thickness between 100 and 300 μm.

4. The leadframe strip according to claim 1 wherein said surface configuration of said base metal for said leadframe units comprises an adherent layer of nickel on said base metal, and a layer of palladium or palladium/gold adherent on said nickel.

5. The leadframe strip according to claim 4 wherein said nickel layer has a thickness between 0.2 and 3.0 μm.

6. The leadframe strip according to claim 4 wherein said palladium layer has a thickness between 20 and 75 nm.

7. The leadframe strip according to claim 4 wherein said gold layer has a thickness between 2 and 5 nm.

8. The leadframe strip according to claim 1 wherein said surface configuration of said base metal for said rails comprises said base metal as modified by the manufacturing process flow.

9. The leadframe strip according to claim 1 wherein said surface configuration of said base metal for said rails comprises an adherent layer of nickel on said base metal.

10. The leadframe strip according to claim 9 wherein said nickel layer has a thickness between 0.2 and 3.0 μm.

11. A leadframe strip for use in the assembly of integrated circuit devices, said strip made from a sheet of base metal, comprising:
a series of leadframe units formed in said base metal and arranged in linear progression so that each unit is interconnected with its adjacent neighbors by supporting rails, wherein said rails are positioned along the outer edges of said strip, thus holding said strip together;
said strip having an adherent first layer comprising nickel on said base metal; and
an adherent second layer of metal on said nickel layer, wherein said second metal is selected for improved adherence to encapsulation compounds and bonding wires;
said second layer selectively placed on said units, leaving said rails uncovered.

12. A method for fabricating a leadframe strip for use in the assembly and packaging of integrated circuit devices, comprising the steps of:
forming a plurality of leadframe units from a sheet of base metal, each of said units comprising a mount pad for an integrated circuit chip and a plurality of lead segments, said series of units arranged in linear progression so that each unit is interconnected with its adjacent neighbors by supporting rails, wherein said rails are positioned along the outer edges of said strip and are holding said strip together;
selectively masking said rails, thereby leaving said leadframe units exposed;
plating a layer of a metal selected for improved adherence to encapsulation compounds and bonding wires; and
removing said selective mask from said rails.

13. The method according to claim 12 wherein said step of forming a plurality of leadframe units comprises the step of stamping.

14. The method according to claim 12 wherein said step of forming a plurality of leadframe units comprises the step of etching.

15. The method according to claim 12 further comprising the step of plating an additional layer of metal on said leadframe before said layer for improved adhesion is plated.

16. A method for fabricating a semiconductor device using
a transfer molding encapsulation process, comprising:
providing a plurality of integrated circuit chips;
providing a leadframe strip having a series of leadframe units arranged in linear progression so that each unit is interconnected with its adjacent neighbors by supporting rails, wherein said rails are positioned along the outer edges of said strip, thus holding said strip together;
said strip having a metal-containing layer selected for improved adherence to encapsulation compounds and bonding wires, selectively placed on said units so that said rails remain uncovered;
attaching one of said chips at a time to its respective leadframe unit;
wire bonding each of said chips to their respective electrical leadframe connections, completing the assembly of said chips;
placing said strip into the cavity of a mold, closing said mold and pressuring molding compound through runners and a gate into said cavity for encapsulating said assembled chips, whereby said compound in said runners, in order to reach said gates into said cavity, crosses said rails without adhering to said rails;
opening said mold for unloading said strip, thereby separating said rails from said compound remaining in said runners.

17. The method according to claim 16 wherein said metal-containing layer is selected in conjunction with said molding compound so that said their mutual adhesion is maximized.

18. The method according to claim 16 wherein said metal layer for improved adherence comprises palladium or palladium/gold.

19. The method according to claim 16 wherein said layer for improved adherence comprises a metal oxide.
